(19) United States
(12) Patent Application Publication
(10) Pub. No.: US 2024/0321915 A1
(43) Pub. Date: Sep. 26, 2024

(54) PHOTOELECTRIC CONVERSION APPARATUS, METHOD FOR MANUFACTURING PHOTOELECTRIC CONVERSION APPARATUS, AND EQUIPMENT

(71) Applicant: CANON KABUSHIKI KAISHA, Tokyo (JP)

(72) Inventors: HISANORI HOSAKA, Kanagawa (JP); TAKASHI USUI, Kanagawa (JP); KAZUHIRO MORIMOTO, Kanagawa (JP); ALICE EHARA, Kanagawa (JP)

(21) Appl. No.: 18/595,726

(22) Filed: Mar. 5, 2024

(30) Foreign Application Priority Data
Mar. 20, 2023 (JP) 2023-044141

(51) Int. Cl. H01L 27/146

(52) U.S. Cl. CPC H01L 27/14623; H01L 27/14643

(57) ABSTRACT

A photoelectric conversion apparatus includes photoelectric conversion elements that each include a photoelectric conversion unit disposed on a side of a first surface of a semiconductor layer, and in which light enters from a side of a second surface opposite to the first surface, a first element isolation portion that extends in the semiconductor layer from the first surface toward the second surface, and a second element isolation portion that extends in the semiconductor layer from the second surface toward the first surface and comes into contact with the first element isolation portion. The coated portion is in contact with the second element isolation portion.

### BACKGROUND OF THE INVENTION

### Field of the Invention

The technique of the present disclosure relates to a photoelectric conversion apparatus, a method for manufacturing the photoelectric conversion apparatus, and equipment.

### Description of the Related Art

Selecting a structure and a material of an element isolation portion between photoelectric conversion elements provides an effect of preventing light emission crosstalk and a decrease in sensitivity. U.S. Patent Application Publication No. 2015/0372031 describes an isolation layer that is an element isolation portion provided between photoelectric conversion elements in a photoelectric conversion apparatus.

However, the isolation layer formed in the above photoelectric conversion apparatus is formed by an insulation layer, and therefore there is a probability that the isolation layer cannot sufficiently reduce diffusion of electrons photoelectrically converted by the photoelectric conversion elements, and it is not possible to suitably prevent light emission crosstalk. Furthermore, there is a probability that, when light having entered the photoelectric conversion elements attenuates in the isolation layer, sensitivity of the photoelectric conversion elements lowers.

The technique of the present disclosure has been made with the foregoing problem in view, and an object of the present disclosure is to provide a photoelectric conversion apparatus that includes element isolation portions that achieve both of improvement of light emission crosstalk and maintenance of sensitivity.

According to some embodiments, a photoelectric conversion apparatus that includes a semiconductor layer, the photoelectric conversion apparatus including a plurality of photoelectric conversion elements that each include a photoelectric conversion unit disposed on a side of a first surface of the semiconductor layer, and in which light of a light source enters from a side of a second surface opposite to the first surface of the semiconductor layer, a first element isolation portion that extends in the semiconductor layer from the first surface toward the second surface between a neighboring first photoelectric conversion element and second photoelectric conversion element of the plurality of photoelectric conversion elements, and a second element isolation portion that extends in the semiconductor layer from the second surface toward the first surface between the first photoelectric conversion element and the second photoelectric conversion element, and comes into contact with the first element isolation portion, wherein the first element isolation portion includes a coated portion whose conductive material is coated with an insulation material containing silicon oxide, silicon nitride, silicon oxynitride, or a combination of the silicon oxide, the silicon nitride, and the silicon oxynitride, the coated portion is in contact with the second element isolation portion, and a film thickness of the insulation material in a cross section vertical to a substrate on which the semiconductor layer is laminated is 10 nm or more in a case where the insulation material is silicon nitride, 150 nm or more in a case where the insulation material is silicon oxide, and 50 nm or more in a case where the insulation material is silicon oxynitride.

In addition, according to some embodiments, a method for manufacturing a photoelectric conversion apparatus, the method including disposing on a semiconductor layer a plurality of photoelectric conversion elements that each include a photoelectric conversion unit disposed on a side of a first surface of the semiconductor layer, and in which light of a light source enters from a side of a second surface opposite to the first surface of the semiconductor layer, and forming a first element isolation portion that extends in the semiconductor layer from the first surface toward the second surface between a neighboring first photoelectric conversion element and second photoelectric conversion element of the plurality of photoelectric conversion elements, and includes a coated portion whose conductive material is coated with an insulation material containing silicon oxide, silicon nitride, silicon oxynitride, or a combination of the silicon oxide, the silicon nitride, and the silicon oxynitride, wherein a film thickness of the insulation material in a cross section vertical to a substrate on which the semiconductor layer is laminated is 10 nm or more in a case where the insulation material is silicon nitride, 150 nm or more in a case where the insulation material is silicon oxide, and 50 nm or more in a case where the insulation material is silicon oxynitride.

In addition, according to some embodiments, equipment that includes the photoelectric conversion apparatus as described above, further including at least one of an optical device that supports the photoelectric conversion apparatus, a control device that controls the photoelectric conversion apparatus, a processing device that processes a signal output from the photoelectric conversion apparatus, a display device that displays information obtained by the photoelectric conversion apparatus, a storage device that stores information obtained by the photoelectric conversion apparatus, and a machine device that operates on a basis of information obtained by the photoelectric conversion apparatus.

Further features of the present invention will become apparent from the following description of exemplary embodiments with reference to the attached drawings.

### SUMMARY OF THE INVENTION

### Brief Description of the Drawings

FIG. 1 is a plan view of a photoelectric conversion apparatus according to an embodiment;

FIGS. 2A and 2B are cross-sectional views of the photoelectric conversion apparatus according to a first embodiment;

FIGS. 3A and 3B are views illustrating a method for manufacturing element isolation portions of the photoelectric conversion apparatus according to the first embodiment;

FIGS. 4A to 4C are views illustrating the method for manufacturing the element isolation portions of the photoelectric conversion apparatus according to the first embodiment;

FIGS. 5A and 5B are views illustrating the method for manufacturing the element isolation portions of the photoelectric conversion apparatus according to the first embodiment;

FIGS. 6A to 6D are enlarged cross-sectional views of the element isolation portions of the photoelectric conversion apparatus according to the first embodiment;

FIGS. 7A and 7B are cross-sectional views of the photoelectric conversion apparatus according to a second embodiment;

FIG. 8 is a cross-sectional view of the photoelectric conversion apparatus according to a third embodiment;

FIG. 9 is a cross-sectional view of the photoelectric conversion apparatus according to the third embodiment; and

FIG. 10 is a schematic view of equipment that includes the photoelectric conversion apparatus according to a fourth embodiment.

### DESCRIPTION OF THE EMBODIMENTS

Hereinafter, embodiments of the present invention will be described in detail with reference to the drawings. Note that terms (e.g., “upper”, “lower”, “right”, and “left”, and different terms including these terms) indicating specific directions and positions are used as needed in the following description. Use of these terms is to help easily understand the embodiments with reference to the drawings, and the meanings of these terms do not limit the technical scope of the present invention. Furthermore, use of these terms is to embody the technical idea of the present invention, and is not to limit the present invention. Components in each embodiment can be added to another embodiment, or replaced with components in another embodiment. Furthermore, the sizes of and the positional relationship between members illustrated in each drawing are exaggerated to clarify description in some cases.

### First Embodiment

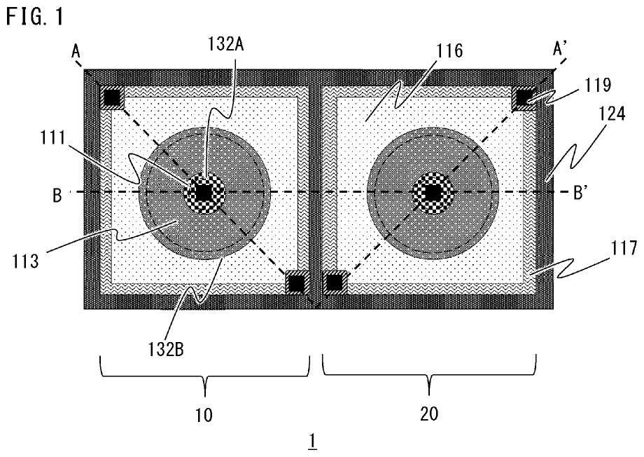

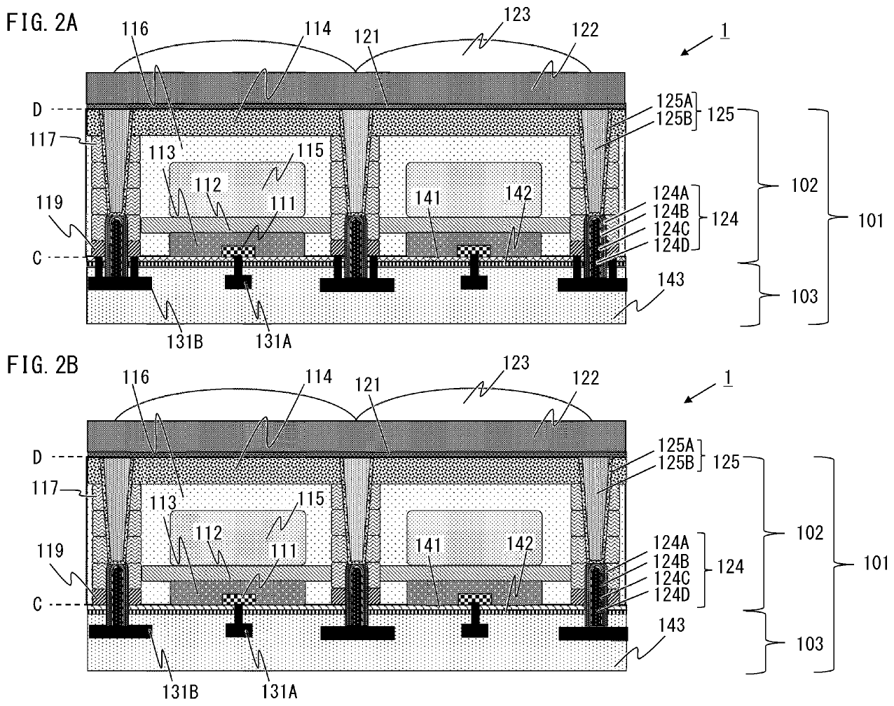

A photoelectric conversion apparatus according to the first embodiment will be described with reference to FIGS. 1, 2A and 2B. FIG. 1 is a plan view of two pixels of a photoelectric conversion apparatus 1 according to the present embodiment, and is a view in plan view when the pixels are seen from a surface opposing to light incident surfaces of the pixels. Furthermore, FIG. 2A is a cross-sectional view of the two pixels in a direction vertical to a substrate of the photoelectric conversion apparatus 1 according to the present embodiment, and corresponds to a cross section taken along line A-A′ in FIG. 1. Furthermore, FIG. 2B corresponds to a cross section taken along line B-B′ in FIG. 1.

The present embodiment assumes that the photoelectric conversion apparatus 1 is, for example, an avalanche multiplication-type photoelectric conversion apparatus. First, the structure and the function of the photoelectric conversion apparatus 1 will be described. As illustrated in FIG. 1, the photoelectric conversion apparatus 1 includes an Avalanche PhotoDiode (APD) 10 that is a first photoelectric conversion element constituting one pixel, and an Avalanche PhotoDiode (APD) 20 that is a second photoelectric conversion element constituting another pixel. Furthermore, as illustrated in FIGS. 2A and 2B, the photoelectric conversion apparatus 1 includes a substrate 101 including a semiconductor layer 102 and a wiring layer 103.

The semiconductor layer 102 is, for example, a semiconductor layer that is an N-type semiconductor region. The semiconductor layer 102 is formed of, for example, silicon. The semiconductor layer 102 includes a first surface (a surface indicated by “A” in the figure) and an opposing second surface (a surface indicated by “B” in the figure). A first surface C and a second surface D of the semiconductor layer 102 are the top surface and the back surface of the semiconductor layer 102, respectively, and are boundary surfaces with respect to other members. Furthermore, the first surface C side is a side on which photoelectric conversion units of pixels are disposed, and the second surface D side is a side on which light from light sources are incident.

Furthermore, the semiconductor layer 102 includes an N-type first semiconductor region 111, third semiconductor region 113, fifth semiconductor region 115, and sixth semiconductor region 116. Furthermore, the semiconductor layer 102 includes a P-type second semiconductor region 112, fourth semiconductor region 114, seventh semiconductor region 117, and ninth semiconductor region 119. In the following description, the P-type semiconductor region is a first conduction-type semiconductor region, and the N-type semiconductor region is a second conduction-type semiconductor region.

In the present embodiment, in the cross section illustrated in FIGS. 2A and 2B, the N-type first semiconductor region 111 is formed near the surface opposing to the light incident surface, and the N-type third semiconductor region 113 is formed around the first semiconductor region 111. The P-type second semiconductor region 112 is formed on the first semiconductor region 111 and the third semiconductor region 113. Furthermore, the N-type fifth semiconductor region 115 is formed on the second semiconductor region 112, and the N-type sixth semiconductor region 116 is formed around the fifth semiconductor region 115.

FIG. 1 also illustrates the positional relationship between a cathode wiring 131A and an anode wiring 131B in FIGS. 2A and 2B. As illustrated in FIG. 1, in plan view of the photoelectric conversion apparatus 1, a cathode wiring end 132A is disposed so as to be enclosed in the first semiconductor region 111, and the anode wiring end 132B is disposed in a region that does not overlap the third semiconductor region 113.

An impurity concentration of the first semiconductor region 111 is higher than impurity concentrations of the third semiconductor region 113 and the fifth semiconductor region 115. A PN junction is formed between the P-type second semiconductor region 112 and the N-type first semiconductor region 111. By making the impurity concentration of the second semiconductor region 112 lower than the impurity concentration of the first semiconductor region 111, a region of the second semiconductor region 112 that overlaps the first semiconductor region 111 becomes a depleted layer region in plan view of the photoelectric conversion apparatus 1. In this case, a potential difference between the first semiconductor region 111 and the second semiconductor region 112 is greater than a potential difference between the second semiconductor region 112 and the fifth semiconductor region 115. Furthermore, this depleted layer region extends to a partial region of the first semiconductor region 111, and a strong electric field is induced in the extended depleted layer region. This strong electric field causes avalanche multiplication in the depleted layer region that extends to the partial region of the first semiconductor region 111, and a current based on an amplified charge is output as a signal charge.

Light having entered the APDs 10 and 20 from the second surface D side of the photoelectric conversion apparatus 1 is photoelectrically converted, and, when avalanche multiplication occurs in the above depleted layer region (avalanche multiplication region), the generated first conduction-type charge gathers in the first semiconductor region 111. Note that, although the third semiconductor region 113 and the fifth semiconductor region 115 are formed to have substantially the same sizes in plan view of the photoelectric conversion apparatus 1 in FIGS. 2A and 2B, the size of each semiconductor region is not limited to this. By, for example, forming the fifth semiconductor region 115 larger than the third semiconductor region 113 in plan view of the photoelectric conversion apparatus 1, it is also possible to collect the charge from a wider range to the first semiconductor region 111. Furthermore, the third semiconductor region 113 may be the P-type semiconductor region instead of the N-type semiconductor region.

Furthermore, a first element isolation portion 124 and a second element isolation portion 125 are provided between the APD 10 and the APD 20. The first element isolation portion 124 extends from the surface that opposes to the light incident surface of the semiconductor layer 102 toward the light incident surface, that is, from the first surface C toward the second surface D of the substrate 101. Furthermore, the second element isolation portion 125 extends from the light incident surface side of the semiconductor layer 102, that is, the second surface D toward the first surface C of the substrate such that the second element isolation portion 125 comes into contact with the first element isolation portion 124 in a direction (an upper/lower direction in the figure) vertical to the substrate 101. Furthermore, the first element isolation portion 124 is formed so as to fit in the seventh semiconductor region 117 and in the ninth semiconductor region 119 in a direction (a left/right direction in the figure) horizontal to the substrate 101.

The first element isolation portion 124 includes a coated portion 124E whose conductive material is coated with insulation materials. The coated portion 124E includes a first portion 124A, a second portion 124B, a third portion 124C, and a fourth portion 124D. Furthermore, the coated portion 124E includes at least one or more conductive materials, and at least one or more insulation materials. More specifically, the first portion 124A and the second portion 124B are formed of silicon oxide, silicon nitride, silicon oxynitride, a combination thereof, or the like as the insulation materials. Furthermore, the third portion 124C is formed of titanium or titanium nitride that is a barrier metal of the conductive material. Furthermore, the fourth portion 124D is formed of tungsten, titanium, gold, silver, copper, platinum, or the like as the conductive material.

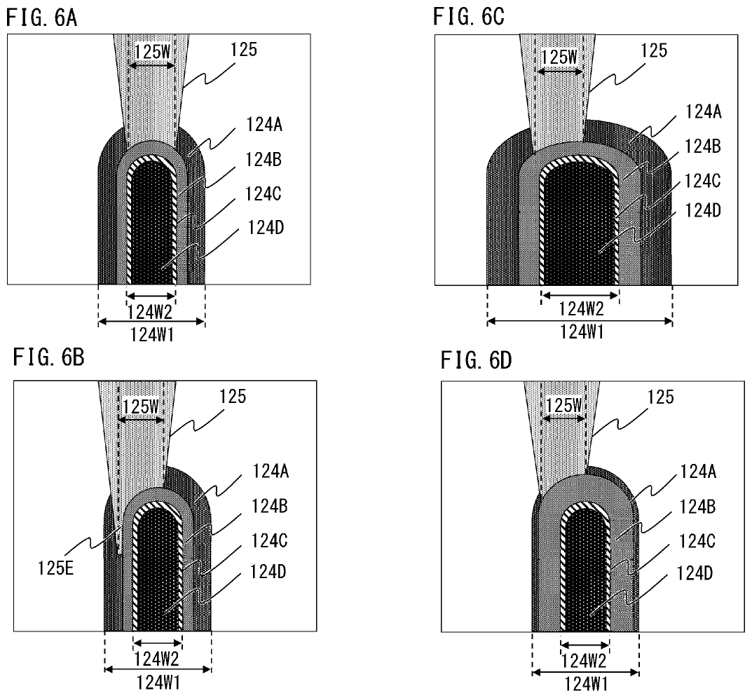

Furthermore, the second element isolation portion 125 includes a first portion 125A and a second portion 125B. The first portion 125A of the second element isolation portion 125 is formed of aluminum oxide, hafnium oxide, or the like as a fixed charge film. Furthermore, the second portion 125B is formed of silicon oxide or the like. The coated portion 124E of the first element isolation portion 124 is in contact with the second element isolation portion 125. Furthermore, a portion is formed at which an interface between the insulation materials that form the coated portion 124E of the first element isolation portion 124 and the end portion on the second surface D side of the first element isolation portion 124 is discontinuous. That is, as illustrated in FIGS. 6A to 6D described later, in the cross section vertical to the substrate 101, a layer of the insulation material (the first portion 124A in FIGS. 6A to 6D) of the first element isolation portion 124 includes a portion that is made discontinuous by the second element isolation portion 125. Furthermore, an interface between the insulation materials and the conductive materials that form the coated portion 124E of the first element isolation portion 124 is continuously connected. That is, as illustrated in FIGS. 6A to 6D described later, in the cross section vertical to the substrate 101, an interface between the second portion 124B and the third portion 124C of the first element isolation portion 124 is not in contact with the second element isolation portion.

Note that, in a case where the coated portion 124E of the first element isolation portion 124 and the second element isolation portion 125 are not in contact with each other, light emission crosstalk in the APDs 10 and 20 is likely to deteriorate. Hence, in the present embodiment, the first element isolation portion 124 and the second element isolation portion 125 are formed such that the coated portion 124E of the first element isolation portion 124 and the second element isolation portion 125 are in contact with each other. Furthermore, the first element isolation portion 124 is formed such that the position of the end portion on the second surface D side of the first element isolation portion 124 is a position deeper in the vertical direction than that of the second semiconductor region 112 when seen from the first surface C. More specifically, the fourth portion 124D that is made of the conductive material in the first element isolation portion 124 is formed extending to a deeper position than that of the second semiconductor region 112 that induces avalanche multiplication when seen from the first surface C side. Thus, when a potential is applied to the fourth portion 124D of the first element isolation portion 124, an electric field is produced, so that the charge from the second semiconductor region 112 that induces avalanche multiplication enters the neighboring APD.

Note that, in a case where the coated portion 124E of the first element isolation portion 124 is formed of the conductive materials alone, a current flows from the second semiconductor region 112 to the first semiconductor region 111 via the first element isolation portion 124. Hence, when the coated portion 124E of the first element isolation portion 124 is formed, the first portion 124A and the second portion 124B made of the insulation materials are embedded before the third portion 124C and the fourth portion 124D made of the conductive materials are embedded. Furthermore, by adopting such a structure of the coated portion 124E, it is possible to expect an effect of reducing a dark current while reducing metal diffusion to the semiconductor layer 102.

Hereinafter, a specific configuration of the coated portion 124E of the first element isolation portion 124 will be described. A length from the first surface C to the distal end of the coated portion 124E is L1 in the cross section (the cross section illustrated in FIGS. 2A and 2B) vertical to the substrate 101 of the photoelectric conversion apparatus 1. Furthermore, the thickness of the first portion 124A of the coated portion 124E is 124AT, and the thickness of the second portion 124B is 124BT. Furthermore, a sum of the thicknesses of the first portion 124A and the second portion 124B is L2. Note that details of the thicknesses 124AT, 124BT, L1, and L2 of the first element isolation portion 124 will be described together with an example of a manufacturing method described later. In this regard, the film thickness determined according to following equation (1) can cause the layers (the first portion 124A and the second portion 124B) made of the insulation materials in the first element isolation portion 124 to function as etching stop films when the second element isolation portion 125 is formed by etching.

$$L 2 \geq ( A - L 1 ) \times B \qquad ( 1 )$$

In equation (1), A represents the thickness of the substrate 101, and a time to form a groove of the second element isolation portion 125 becomes long as the substrate 101 becomes thicker. Therefore, the thicknesses required for the etching stop films for absorbing machining variations of the second element isolation portion 125 increase. Furthermore, in equation (1), B represents a constant determined according to etch selectivity of a material used for the substrate 101. For example, B=0.003 holds in a case where the material used for the substrate 101 is silicon nitride, B=0.015 holds in a case where the material used for the substrate 101 is silicon oxynitride, and B=0.044 holds in a case where the material used for the substrate 101 is silicon oxide.

On the other hand, the second element isolation portion 125 is formed of a reflection member having the insulation property. The second element isolation portion 125 reflects light that enters the substrate 101 to cause avalanche multiplication in the semiconductor layer 102. The reflection member of the second element isolation portion 125 is a member formed of silicon oxide or silicon nitride, and the fixed charge film is a member formed of aluminum oxide, hafnium oxide, or a combination of aluminum oxide or hafnium oxide. Furthermore, since a smaller extinction coefficient can prevent attenuation of incident light, it is preferable to use a member having a smaller extinction coefficient as the reflection member of the second element isolation portion 125.

As illustrated in FIGS. 2A and 2B, a fixed charge film 121, a planarization film 122, and a microlens 123 containing aluminum oxide or hafnium oxide are further formed on the light incident surface side, that is, the second surface D side of the semiconductor layer 102. The wiring layer 103 including a conductive band and an insulation film is provided on a surface on an opposite side to the light incident surface, that is, on the first surface C side of the semiconductor layer 102, and a wiring structure including an oxide film 141, a protection film 142, and a conductive band from a side closer to the semiconductor layer 102 is laminated.

An interlayer film 143 that is an insulation film is provided between a wiring and the semiconductor layer, and between wiring layers. The protection film 142 is a film that protects the semiconductor layer from plasma damages or metal contamination at a timing of etching processing. Silicon nitride that is a nitride film is generally used. However, silicon oxynitride, silicon carbide, silicon nitride carbide, or the like may be used. Furthermore, the wiring layer 103 includes the cathode wiring 131A and the anode wiring 131B, the cathode wiring 131A is connected to the first semiconductor region 111, and the anode wiring 131B supplies a voltage to the seventh semiconductor region 117 via the ninth semiconductor region 119 that is an anode contact.

The photoelectric conversion apparatus 1 according to the present embodiment can improve sensitivity while suppressing light emission crosstalk for neighboring pixels by combining the first element isolation portion 124 and the second element isolation portion 125. Furthermore, when an etching device forms a groove in the substrate 101 that is a silicon substrate, it is possible to prevent silicon that is being machined from being exposed to a metal atmosphere, and reduce occurrence of a dark current. Furthermore, the thicknesses of the insulation materials that cover an embedded metal around the element isolation portions are uniformly kept at a time of machining of the first element isolation portion 124 and the second element isolation portion 125, so that it is possible to reduce a decrease in the pressure resistance between the conductive material and the silicon substrate.

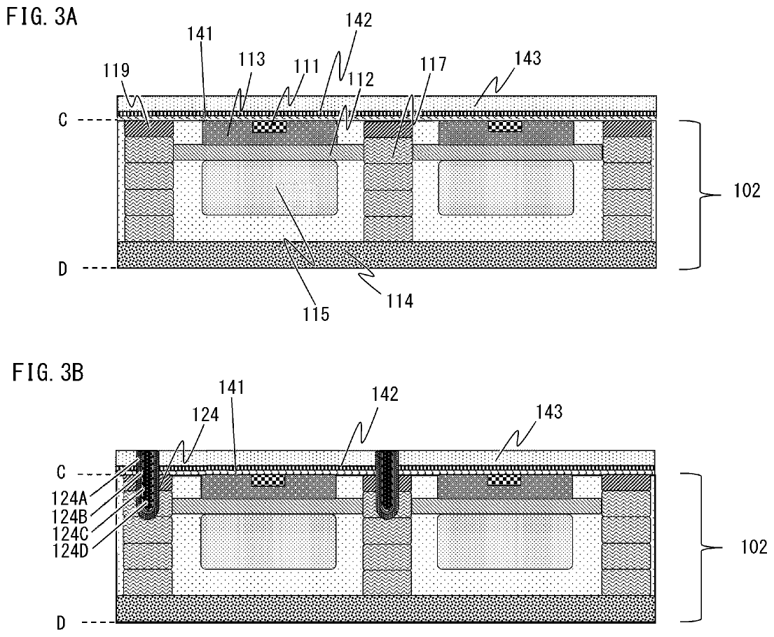

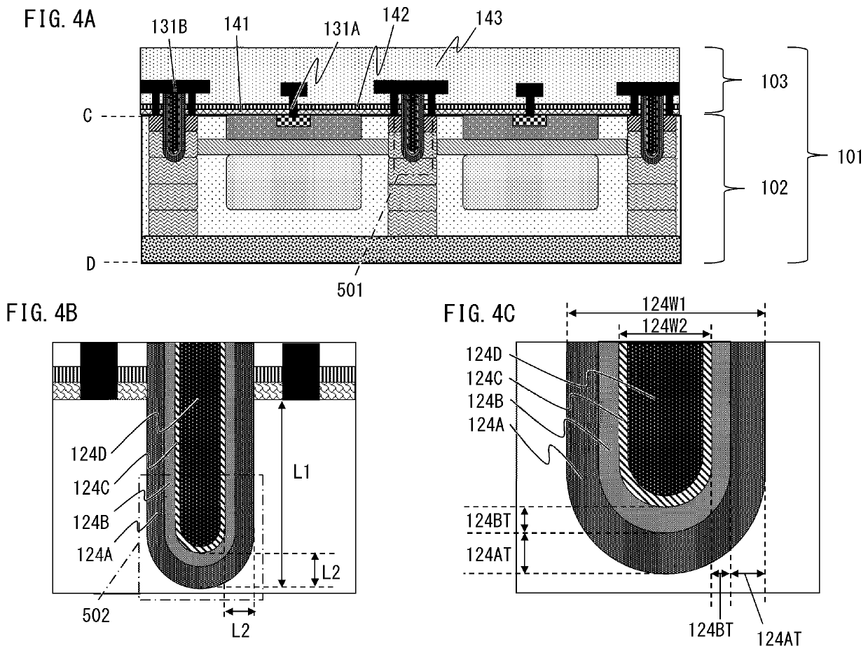

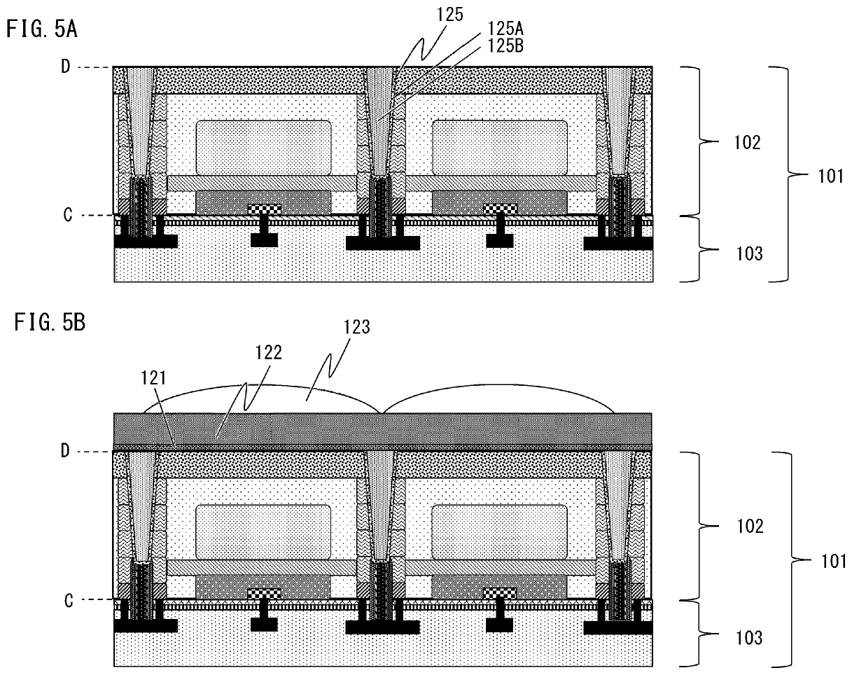

(Method for Manufacturing Photoelectric Conversion Device) The method for manufacturing the photoelectric conversion apparatus 1 according to the present embodiment will be described below with reference to FIGS. 3A, 3B, 4A to 4C, 5A, and 5B. FIGS. 3A, 3B, and 4A to 4C illustrate processes in which the substrate including the semiconductor layer 102 is used as a support substrate. Furthermore, FIGS. 4A to 4C are enlarged views of the distal end of the first element isolation portion 124, and illustrate states of the first element isolation portion 124 before the second element isolation portion 125 comes into contact with the first element isolation portion 124. Note that FIG. 4B is the enlarged view of a portion indicated by a rectangle 501 in FIG. 4A, and FIG. 4C is the enlarged view of a portion indicated by a rectangle 502 in FIG. 4B. FIGS. 5A and 5B are views illustrating a manufacturing process after each layer that constitutes the photoelectric conversion apparatus 1 is laminated.

As illustrated in FIG. 3A, the first semiconductor region 111 to the ninth semiconductor region 119 are formed in the semiconductor layer 102 by repeating processes such as photolithography, ion implantation, and heat diffusion. Next, as illustrated in FIG. 3B, the first element isolation portion 124 is formed in the semiconductor layer 102 by etching. In order to reduce occurrence of a dark current due to etching damages, sacrificial oxidation or chemical dry etching is performed to remove damages caused on the surface of the first element isolation portion 124. Furthermore, by removing the damages, the bottom portion of the first element isolation portion 124 has a round shape, and a stress is relaxed, so that it is possible to expect an effect of reducing occurrence of the dark current. Furthermore, by removing silicon contained in the semiconductor layer 102 by anisotropic dry etching, the groove shape of the first element isolation portion 124 is formed.

Here, the thickness of the silicon layer included in the semiconductor layer 102, that is, a suitable distance from the first surface C to the second surface D in which the semiconductor region is formed in the cross section of the photoelectric conversion apparatus 1 is at least 3.5 μm and not more than 4.5 μm. Furthermore, the suitable depth of a groove of the first element isolation portion 124 is at least 900 nm and not more than 1.5 μm, and the suitable width of the groove is at least 300 nm and not more than 600 nm in the cross section of the photoelectric conversion apparatus 1. In this case, it is desirable to form the first element isolation portion 124 more broadly than the second element isolation portion 125 as much as possible.

By increasing a contact area of the second element isolation portion 125 and the first element isolation portion 124 when the second element isolation portion 125 is formed, it is possible to reduce a contact failure between the second element isolation portion 125 and the first element isolation portion 124 due to position shift of each portion in the process of forming the second element isolation portion 125, and reduce occurrence of crosstalk. When the first portion 124A to the fourth portion 124D of the first element isolation portion 124 are formed, insulation materials are disposed first by CVD or the like. In the present embodiment, 150 nm of silicon oxide and 10 nm of silicon nitride that function as the etching stop films of silicon etching are laminated and disposed. As this insulation film layer, silicon oxynitride may be used according to a purpose, and these films may be combined and used.

As illustrated in FIGS. 4B and 4C, the film thickness of silicon oxide at the end portion of the first element isolation portion 124 is 124AT, and the film thickness of silicon nitride is 124BT in the vertical direction of the cross section vertical to the substrate 101. Note that, as illustrated in FIGS. 4B and 4C, the film thickness of silicon oxide at the side surface portion of the first element isolation portion 124 may be also 124AT, and the film thickness of silicon nitride may be also 124BT in the horizontal direction of the cross section vertical to the substrate 101. Here, the film thicknesses of the insulation materials at the end portion and the side surface portion of the first element isolation portion 124 are the same. Note that the first element isolation portion 124 may be formed according to the manufacturing method such that the film thicknesses of the insulation materials at the side surface portion of the first element isolation portion 124 are smaller than the film thicknesses at the end portion. Furthermore, as illustrated in the figures, the depth of the groove of the first element isolation portion 124 from the first surface C is L1, and the sum of the thicknesses of 124AT and 124BT that are the thicknesses of the insulation materials contained in the first element isolation portion 124 is L2.

Taking into account a minimum film thickness at which etching stop functions even in a case of a single film, and embeddability of the conductive materials of the element isolation portions, the film thickness L2 in a case where the insulation material is silicon nitride is preferably at least 10 nm and not more than 200 nm. Similarly, the film thickness L2 in a case where the insulation material is silicon oxynitride is preferably at least 50 nm and not more than 200 nm, and, the film thickness L2 in a case where the insulation material is silicon oxide is preferably at least 150 nm and not more than 200 nm. Note that silicon nitride has particularly high selectivity with respect to silicon etching, and consequently sufficiently functions as the etching stop film even when the film thickness is small.

Subsequently, the conductive materials that form the first element isolation portion 124 are embedded by CVD, the sol-gel process, or the like. In this regard, the embedding depth of the conductive materials measured from the first surface C is the same as the position of the second semiconductor region 112, or is the depth that goes beyond the position of the second semiconductor region 112. The embedding depth of the conductive materials is 750 nm in the present embodiment, yet may be changed as appropriate according to design of the photoelectric conversion apparatus 1. Furthermore, as illustrated in FIG. 4A, processes such as film formation, photolithography, and etching are repeated to form the wiring layer 103 from a contact plug to an unillustrated joint metal.

Next, a method for manufacturing the second element isolation portion 125 will be described with reference to FIGS. 5A and 5B. FIG. 5A illustrates a state after the substrate 101 is bonded to another support substrate or a circuit board, and the substrate 101 is thinned. A dry etching device etches the silicon layer of the substrate 101 from the light incident surface side, that is, the second surface D side until the silicon layer contacts the inner wall of the first element isolation portion 124. Here, since, when the metal films of the third portion 124C and the fourth portion 124D are exposed during etching, metal atoms diffuse in the silicon substrate and cause a dark current, etching is performed such that the conductive materials of the third portion 124C and the fourth portion 124D are not exposed.

Furthermore, the silicon oxide and the silicon nitride disposed in the first element isolation portion 124 function as the etching stop films of silicon etching, and the groove of the second element isolation portion 125 comes into contact with the first element isolation portion 124. Furthermore, etching stops at the first portion 124A or the second portion 124B of the first element isolation portion 124, and the groove of the second element isolation portion 125 does not reach the third portion 124C and the fourth portion 124D. Note that silicon etching selectivity of the silicon nitride is higher than that of the silicon oxide. Hence, an etching rate is lowered from the first portion 124A to the second portion 124B stepwise during etching at a time of formation of the second element isolation portion 125. Consequently, it is possible to make distances between the inner wall of the first element isolation portion 124, and the third portion 124C and the fourth portion 124D made of the conductive materials uniform.

Lastly, the reflection member is embedded in the groove of the second element isolation portion 125 by CVD, the sol-gel method, or the like. For the reflection member, the fixed charge film, the oxide film, the nitride film, the metal film, or a plurality of combinations thereof can be used. As illustrated in FIG. 5B, the fixed charge film 121, the planarization film 122, and the microlens 123 are formed by the same machining method as that used for the wiring layer 103.

(Shape of Element Isolation Portion) Next, the shape of a connection portion of the first element isolation portion 124 and the second element isolation portion 125, and a process of etching stop at a time when the second element isolation portion 125 is machined according to the present embodiment will be described with reference to FIGS. 6A and 6D.

FIG. 6A is a cross-sectional schematic view illustrating the enlarged connection portion of the first element isolation portion 124 and the second element isolation portion 125 in FIGS. 2A and 2B. As illustrated in FIG. 6A, the groove of the second element isolation portion 125 is etched taking a sufficient time until the groove reaches the first element isolation portion 124.

In the etching process of machining the second element isolation portion 125, the groove of the second element isolation portion 125 first reaches the silicon oxide layer of the first portion 124A, and then reaches the silicon nitride layer of the second portion 124B. Since the silicon etching selectivity of the silicon nitride is higher than that of the silicon oxide, the etching rate is sequentially decreased during etching of the second element isolation portion 125 to keep uniformity of a machining depth.

FIGS. 6A to 6D illustrate a case where, during etching of the second element isolation portion 125, the groove of the second element isolation portion 125 penetrates the silicon oxide layer of the first element isolation portion 124 and reaches the silicon nitride layer, and etching stops. In this regard, etching may also stop in a state where the groove of the second element isolation portion 125 is in the silicon oxide layer or the silicon nitride layer due to an overetching amount or variations.

FIG. 6B is a cross-sectional view in a case where the second element isolation portion 125 is offset from the first element isolation portion 124. In a case where the second element isolation portion 125 is formed using anisotropic etching, the etching rate is not partially decreased at a portion at which there is no silicon nitride layer under the silicon oxide layer of the first element isolation portion 124. As a result, as illustrated in FIG. 6B, there is a probability that a portion 125E is formed at which the groove of the second element isolation portion 125 deeply gets in the first portion 124A is formed along the second portion 124B of the first element isolation portion 124. There is a probability that the material of the second element isolation portion 125 hardly gets in this portion 125E, and faulty embedding of the material occurs. Hence, in the present embodiment, as illustrated in FIG. 6C, a width 124W1 of the groove and a width 124W2 of the conductive materials of the first element isolation portion 124 are made 100 nm or more larger than a width 125W of the second element isolation portion 125 in the cross section of the photoelectric conversion apparatus 1. Alternatively, as illustrated in FIG. 6D, the silicon nitride layer that forms the second portion 124B of the first element isolation portion 124 is made thicker than 10 nm to dispose. Consequently, it is possible to more suitably achieve connection of the first element isolation portion 124 and the second element isolation portion 125.

In the present embodiment, while a decrease in the pressure resistance between the conductive materials and the silicon substrate is suitably reduced, the second element isolation portion 125 is brought close to the conductive materials of the first element isolation portion 124 as much as possible, and is connected with the first element isolation portion 124. Hence, the silicon oxide layer and the silicon nitride layer are laminated in the first element isolation portion 124. However, as long as requirement of design of the photoelectric conversion apparatus 1 cab be met, the film thickness of each layer and a ratio of the film thicknesses may be changed.

### Second Embodiment

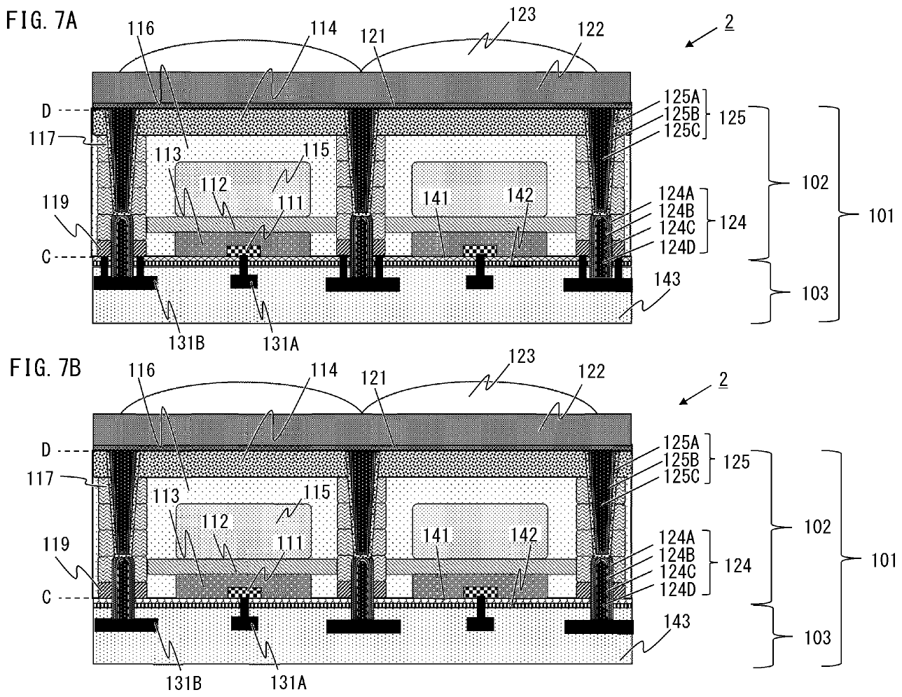

Next, the photoelectric conversion apparatus according to the second embodiment will be described with reference to FIGS. 7A and 7B. Note that components that are common to those in the first embodiment will be assigned the same reference numerals, detailed description thereof will be omitted, and differences from the first embodiment will be mainly described below. FIG. 7A is a cross-sectional view of two pixels of a photoelectric conversion apparatus 2 according to the second embodiment in the direction vertical to the substrate, and corresponds to the cross section taken alone line A-A′ in FIG. 1. Furthermore, FIG. 7B corresponds to the cross section taken along B-B′ in FIG. 1.

In the present embodiment, by embedding the metal reflection member in the groove of the second element isolation portion 125 formed similarly to the first embodiment, it is possible to cause the second element isolation portion 125 to reflect incident light, and cause avalanche multiplication in the semiconductor layer 102. The second element isolation portion 125 includes the first portion 125A, the second portion 125B, and a third portion 125C. The first portion 125A of the second element isolation portion 125 contains aluminum oxide, hafnium oxide, or the like as the fixed charge film. Furthermore, the second portion 125B of the second element isolation portion 125 contains silicon oxide or the like. Furthermore, the third portion 125C of the second element isolation portion 125 contains a conductive material such as titanium, gold, silver, copper, platinum, or the like. Furthermore, the first element isolation portion 124 and the second element isolation portion 125 are connected to each other similarly to the first embodiment, so that it is possible to improve sensitivity of the APD 10 and the APD 20 while reducing light emission crosstalk for neighboring pixels.

The fixed charge film 121, the planarization film 122, and the microlens 123 containing aluminum oxide or hafnium oxide are formed on the light incident surface side, that is, the second surface D side of the semiconductor layer 102 of the photoelectric conversion apparatus 2 according to the present embodiment. The wiring layer 103 including the conductive band and the insulation film is provided on the surface on the opposite side to the light incident surface, that is, on the first surface C side of the semiconductor layer 102, and the wiring structure including the oxide film 141, the protection film 142, and the conductive band from the side closer to the semiconductor layer 102 is laminated.

The interlayer film 143 that is the insulation film is provided between the wiring and the semiconductor layer, and between wiring layers. The protection film 142 is the film that protects the semiconductor layer from plasma damages or metal contamination at a timing of etching processing. Silicon nitride that is a nitride film is generally used. However, silicon oxynitride, silicon carbide, silicon nitride carbide, or the like may be used. Furthermore, the wiring layer 103 includes the cathode wiring 131A and the anode wiring 131B, the cathode wiring 131A is connected to the first semiconductor region 111, and the anode wiring 131B supplies the voltage to the seventh semiconductor region 117 via the ninth semiconductor region 119 that is the anode contact.

The photoelectric conversion apparatus 2 according to the present embodiment can improve sensitivity while suppressing light emission crosstalk for neighboring pixels by combining the first element isolation portion 124 and the second element isolation portion 125.

As described above, according to the photoelectric conversion apparatus according to the above embodiment, when the second element isolation portion is formed using the etching device, it is possible to prevent silicon contained in the substrate from being exposed to the metal material during etching. Consequently, the photoelectric conversion apparatus according to the above embodiment can prevent occurrence of a dark current caused by diffusion of metal atoms. Furthermore, the thicknesses of the insulation materials that cover the conductive materials do not become small locally around the connection portion of the first element isolation portion and the second element isolation portion, so that it is possible to reduce a decrease in the pressure resistance between the conductive material and the silicon substrate. Furthermore, the metal material that forms each element isolation portion is hardly influenced by a change in the shape caused by etching, so that it is possible to suppress variations of an electric field produced when a potential is applied to the element isolation portions for charge control, and it is also possible to reduce variations of sensitivity between pixels and between chips.

### Third Embodiment

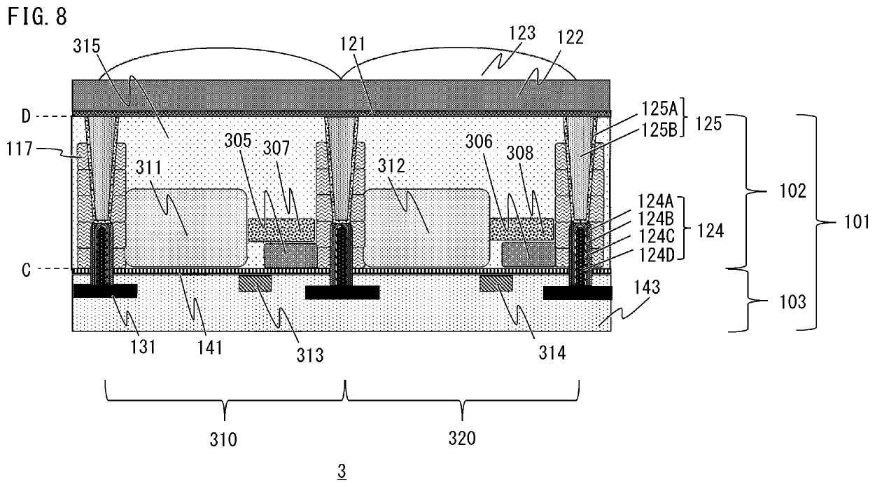

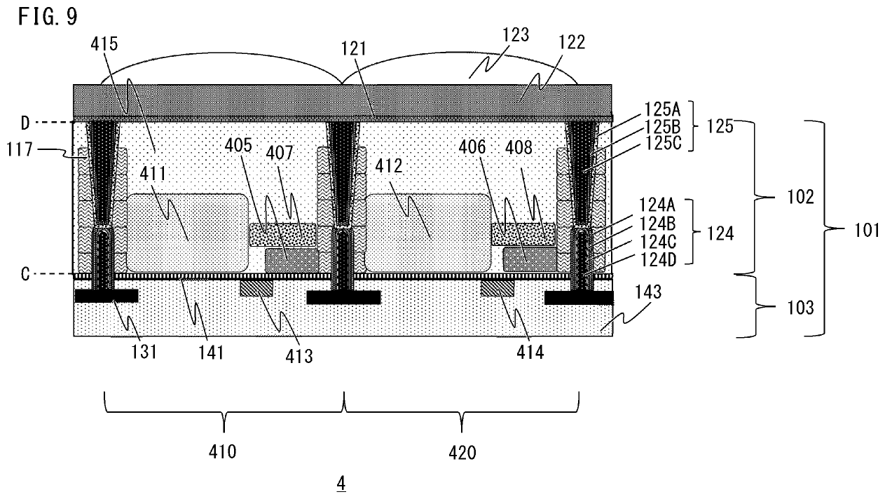

Next, a photoelectric conversion apparatus according to the third embodiment will be described with reference to FIGS. 8 and 9. Note that components that are common to those in the above embodiments will be assigned the same reference numerals, detailed description thereof will be omitted, and differences from the above embodiments will be mainly described below. FIG. 8 is a cross-sectional view of two pixels of a photoelectric conversion apparatus 3 according to the present embodiment in the direction vertical to the substrate, and corresponds to the cross section taken alone line B-B′ in FIG. 1. Furthermore, FIG. 9 is a cross-sectional view of two pixels of a photoelectric conversion apparatus 4 according to the present embodiment in the direction vertical to the substrate, and corresponds to the cross section taken alone line B-B′ in FIG. 1.

The above embodiments have described the photoelectric conversion apparatuses including the APDs. In this regard, the above embodiments are also applicable to photoelectric conversion apparatuses including other device configurations such as Complementary Metal-Oxide Semiconductor (CMOS) image sensors. The photoelectric conversion apparatus 3 illustrated in FIG. 8 corresponds to a modified example of the photoelectric conversion apparatus 1 according to the first embodiment, and the photoelectric conversion apparatus 4 illustrated in FIG. 9 corresponds to a modified example of the photoelectric conversion apparatus 2 according to the second embodiment.

As illustrated in FIG. 8, the photoelectric conversion apparatus 3 according to the present embodiment includes a photodiode 310 that corresponds to the first photoelectric conversion element of the photoelectric conversion apparatus 1, and a photodiode 320 that corresponds to the second photoelectric conversion element. Furthermore, in the photoelectric conversion apparatus 3, N-type semiconductor regions 305, 306, 311, 312, and 315 and P-type semiconductor regions 307 and 308 are disposed instead of the first semiconductor region 111 to the fifth semiconductor region 115 of the photoelectric conversion apparatus 1. Furthermore, the interlayer film 143 of the photoelectric conversion apparatus 3 is provided with gate electrodes 313 and 314 made of a silicide-based material. The semiconductor regions 307 and 308 function as channel stop layers. The semiconductor regions 311 and 312 function as photoelectric conversion units that convert incident light into signals by photoelectric conversion. The gate electrodes 313 and 314 are gate electrodes of transfer transistors that receive the photoelectrically converted signals, and transfer the signals to amplification transistors at a subsequent stage.

As illustrated in FIG. 9, in the photoelectric conversion apparatus 4 according to the present embodiment, N-type semiconductor regions 405, 406, 411, 412, and 415 and P-type semiconductor regions 407 and 408 are disposed instead of the first semiconductor region 111 to the fifth semiconductor region 115 of the photoelectric conversion apparatus 2. Furthermore, the interlayer film 143 of the photoelectric conversion apparatus 4 is provided with gate electrodes 413 and 414 made of a silicide-based material. The semiconductor regions 407 and 408 function as channel stop layers. The semiconductor regions 411 and 412 function as photoelectric conversion units that convert incident light into signals by photoelectric conversion. The gate electrodes 413 and 414 are gate electrodes of transfer transistors that receive the photoelectrically converted signals, and transfer the signals to amplification transistors at a subsequent stage.

The photoelectric conversion apparatuses 3 and 4 according to the present embodiment include photodiodes as the photoelectric conversion elements, and adopt typical components such as the transfer transistors and amplification transistors as reading elements from the photodiodes. Consequently, the photoelectric conversion apparatuses 3 and 4 according to the present embodiment can also improve sensitivity while suppressing light emission crosstalk for neighboring pixels similarly to the photoelectric conversion apparatuses 1 and 2 according to the first and second embodiments.

### Fourth Embodiment

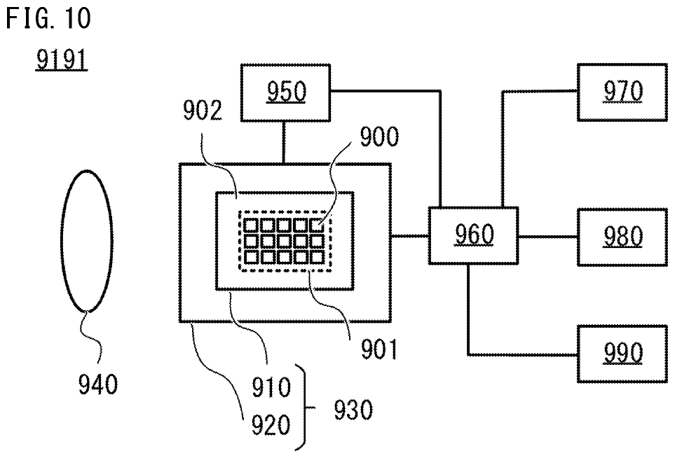

Any of the first to third embodiments described above can be applied to a fourth embodiment. FIG. 10 is a schematic view for describing equipment 9191 including a semiconductor apparatus 930 of the present embodiment. The semiconductor apparatus 930 can be any of the photoelectric conversion apparatuses described in the first to third embodiments, or a photoelectric conversion apparatus obtained by combining a plurality of the embodiments. The equipment 9191 including the semiconductor apparatus 930 will be described in detail. As described above, the semiconductor apparatus 930 can include a semiconductor device 910 having a semiconductor layer, and a package 920 which houses the semiconductor device 910. The package 920 can include a substrate to which the semiconductor device 910 is fixed, and a lid made of glass or the like which faces the semiconductor device 910. The package 920 can further include a joining member such as a bonding wire or a bump which connects a terminal provided on the substrate and a terminal provided on the semiconductor device 910.

The equipment 9191 can include at least any of an optical device 940, a control device 950, a processing device 960, a display device 970, a storage device 980, and a mechanical device 990. The optical device 940 is compliant with the semiconductor apparatus 930. The optical device 940 is, e.g., a lens, a shutter, or a mirror. The control device 950 controls the semiconductor apparatus 930. The control device 950 is a semiconductor apparatus such as, e.g., an ASIC.

The processing device 960 processes a signal output from the semiconductor apparatus 930. The processing device 960 is a semiconductor apparatus such as a CPU or an ASIC for constituting an AFE (analog front end) or a DFE (digital front end). The display device 970 is an EL display device or a liquid crystal display device which displays information (image) obtained by the semiconductor apparatus 930. The storage device 980 is a magnetic device or a semiconductor device which stores information (image) obtained by the semiconductor apparatus 930. The storage device 980 is a volatile memory such as an SRAM or a DRAM, or a non-volatile memory such as a flash memory or a hard disk drive.

The mechanical device 990 has a moving unit or a propulsive unit such as a motor or an engine. In the equipment 9191, a signal output from the semiconductor apparatus 930 is displayed in the display device 970, and is transmitted to the outside by a communication device (not shown) provided in the equipment 9191. In order to do so, it is preferable that the equipment 9191 further includes the storage device 980 and the processing device 960 in addition to a storage circuit and an operation circuit of the semiconductor apparatus 930. The mechanical device 990 may also be controlled on the basis of a signal output from the semiconductor apparatus 930.

In addition, the equipment 9191 is suitably used as electronic equipment such as an information terminal having photographing function (e.g., a smartphone or a wearable terminal) or a camera (e.g., an interchangeable-lens camera, a compact camera, a video camera, or a surveillance camera). The mechanical device 990 in the camera can drive components of the optical device 940 for zooming, focusing, and shutter operation. Alternatively, the mechanical device 990 in the camera can move the semiconductor apparatus 930 for vibration isolation operation.

The equipment 9191 can be transport equipment such as a vehicle, a ship, or a flight vehicle. The mechanical device 990 in the transport equipment can be used as a moving device. The equipment 9191 serving as the transport equipment is suitably used as equipment which transports the semiconductor apparatus 930, or performs assistance and/or automation of driving (manipulation) with photographing function. The processing device 960 for assistance and/or automation of driving (manipulation) can perform processing for operating the mechanical device 990 serving as the moving device based on information obtained in the semiconductor apparatus 930. Alternatively, the equipment 9191 may also be medical equipment such as an endoscope, measurement equipment such as a distance measurement sensor, analysis equipment such as an electron microscope, office equipment such as a copier, or industrial equipment such as a robot.

According to the fifth embodiment, it becomes possible to obtain excellent pixel characteristics. Consequently, it is possible to enhance the value of the semiconductor apparatus 930. At least any of addition of function, an improvement in performance, an improvement in characteristics, an improvement in reliability, an improvement in product yield, a reduction in environmental load, a reduction in cost, a reduction in size, and a reduction in weight corresponds to the enhancement of the value thereof mentioned herein.

Consequently, if the semiconductor apparatus 930 according to the fifth embodiment is used in the equipment 9191, it is possible to improve the value of the equipment as well. For example, when the semiconductor apparatus 930 is mounted on transport equipment and photographing of the outside of the transport equipment or measurement of an external environment is performed, it is possible to obtain excellent performance. Therefore, when the transport equipment is manufactured and sold, it is advantageous to determine that the semiconductor apparatus 930 according to the fifth embodiment is mounted on the transport equipment in terms of increasing the performance of the transport equipment itself. The semiconductor apparatus 930 is suitably used particularly as the transport equipment which performs driving assistance and/or automated driving of the transport equipment by using information obtained by the semiconductor apparatus 930.

Respective embodiments described up to this point, can be appropriately changed within the scope not departing from the technical idea. Incidentally, the contents disclosed in the present specification includes not only the description in the present specification but also all the matters comprehensible from the present specification and the drawings appended in the present specification. Further, the disclosed contents of the present specification include the complement of the concept described in the present specification. Namely, it can be said as follows: a description in the present specification to the effect that “A is larger than B” discloses to the effect that “A is not larger than B” even when the description to the effect that “A is not larger than B” is omitted. This is because it is a premise that the case where there is a description to the effect that “A is larger than B” is accomplished in consideration of the case where “A is not larger than B”.

The technique of the present disclosure can provide a photoelectric conversion apparatus that achieves both of improvement of light emission crosstalk and maintenance of sensitivity.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-044141, filed on Mar. 20, 2023, which is hereby incorporated by reference herein in its entirety.

What is claimed is:

1. A photoelectric conversion apparatus that comprises a semiconductor layer, the photoelectric conversion apparatus comprising:
a plurality of photoelectric conversion elements that each include a photoelectric conversion unit disposed on a side of a first surface of the semiconductor layer, and in which light of a light source enters from a side of a second surface opposite to the first surface of the semiconductor layer;
a first element isolation portion that extends in the semiconductor layer from the first surface toward the second surface between a neighboring first photoelectric conversion element and second photoelectric conversion element of the plurality of photoelectric conversion elements; and
a second element isolation portion that extends in the semiconductor layer from the second surface toward the first surface between the first photoelectric conversion element and the second photoelectric conversion element, and comes into contact with the first element isolation portion, wherein
the first element isolation portion includes a coated portion whose conductive material is coated with an insulation material containing silicon oxide, silicon nitride, silicon oxynitride, or a combination of the silicon oxide, the silicon nitride, and the silicon oxynitride,
the coated portion is in contact with the second element isolation portion, and
a film thickness of the insulation material in a cross section vertical to a substrate on which the semiconductor layer is laminated is 10 nm or more in a case where the insulation material is silicon nitride, 150 nm or more in a case where the insulation material is silicon oxide, and 50 nm or more in a case where the insulation material is silicon oxynitride.

2. The photoelectric conversion apparatus according to claim 1, wherein the second element isolation portion includes an insulation material or a conductive material.

3. The photoelectric conversion apparatus according to claim 1, wherein the second element isolation portion is not in contact with the conductive material of the coated portion.

4. The photoelectric conversion apparatus according to claim 1, wherein a layer of the conductive material and a layer of the insulation material of the coated portion of the first element isolation portion, and a layer of the second element isolation portion are laminated in a direction from the first surface to the second surface.

5. The photoelectric conversion apparatus according to claim 1, wherein a layer of the insulation material of the first element isolation portion includes a portion that is made discontinuous by the second element isolation portion in a cross section vertical to the substrate on which the semiconductor layer is laminated.

6. The photoelectric conversion apparatus according to claim 5, wherein an interface between the layer of the insulation material and a layer of the conductive material of the first element isolation portion is not in contact with the second element isolation portion in the cross section vertical to the substrate on which the semiconductor layer is laminated.

7. The photoelectric conversion apparatus according to claim 1, wherein
the photoelectric conversion apparatus comprises the substrate on which the semiconductor layer and a wiring layer are laminated, and
in a case where a distance from the first surface to a distal end of the coated portion in the cross section vertical to the substrate is L1,
a thickness of the insulation material of the coated portion in a vertical direction or a horizontal direction of the cross section is L2,
a thickness of the substrate is A, and a constant determined according to a material of the substrate is B, following equation (1) is satisfied
$$L 2 \geq ( A - L 1 ) \times B \qquad ( 1 )$$
where B=0.003 holds in a case where the material of the substrate is silicon nitride, B=0.015 holds in a case where the material of the substrate is silicon oxynitride, and B=0.044 holds in a case where the material of the substrate is silicon oxide.

8. The photoelectric conversion apparatus according to claim 1, wherein the first photoelectric conversion element and the second photoelectric conversion element are photodiodes.

9. A photoelectric conversion apparatus that comprises a substrate on which a semiconductor layer and a wiring layer are laminated, the photoelectric conversion apparatus comprising:
a plurality of photoelectric conversion elements that each include a photoelectric conversion unit disposed on a side of a first surface of the semiconductor layer, and in which light of a light source enters from a side of a second surface opposite to the first surface of the semiconductor layer;
a first element isolation portion that extends in the semiconductor layer from the first surface toward the second surface between a neighboring first photoelectric conversion element and second photoelectric conversion element of the plurality of photoelectric conversion elements; and
a second element isolation portion that extends in the semiconductor layer from the second surface toward the first surface between the first photoelectric conversion element and the second photoelectric conversion element, and comes into contact with the first element isolation portion, wherein
the first element isolation portion includes a coated portion whose conductive material is coated with an insulation material,
the coated portion is in contact with the second element isolation portion, and
in a case where a distance from the first surface to a distal end of the coated portion in a cross section vertical to the substrate is L1,
a thickness of the insulation material of the coated portion in a vertical direction or a horizontal direction of the cross section is L2,
a thickness of the substrate is A, and a constant determined according to a material of the substrate is B, following equation (1) is satisfied
$$L 2 \geq ( A - L 1 ) \times B \qquad ( 1 )$$
where B=0.003 holds in a case where the material of the substrate is silicon nitride, B=0.015 holds in a case where the material of the substrate is silicon oxynitride, and B=0.044 holds in a case where the material of the substrate is silicon oxide.

10. The photoelectric conversion apparatus according to claim 9, wherein the insulation material contains silicon oxide, silicon nitride, silicon oxynitride, or a combination of the silicon oxide, the silicon nitride, and the silicon oxynitride.

11. The photoelectric conversion apparatus according to claim 10, wherein a film thickness of the insulation material in a cross section vertical to the substrate on which the semiconductor layer is laminated is 10 nm or more in a case where the insulation material is silicon nitride, 150 nm or more in a case where the insulation material is silicon oxide, and 50 nm or more in a case where the insulation material is silicon oxynitride.

12. The photoelectric conversion apparatus according to claim 9, wherein the second element isolation portion includes an insulation material or a conductive material.

13. The photoelectric conversion apparatus according to claim 9, wherein the second element isolation portion is not in contact with the conductive material of the coated portion.

14. The photoelectric conversion apparatus according to claim 9, wherein a layer of the conductive material and a layer of the insulation material of the coated portion of the first element isolation portion, and a layer of the second element isolation portion are laminated in a direction from the first surface toward the second surface.

15. The photoelectric conversion apparatus according to claim 9, wherein a layer of the insulation material of the first element isolation portion includes a portion that is made discontinuous by the second element isolation portion in a cross section vertical to the substrate on which the semiconductor layer is laminated.

16. The photoelectric conversion apparatus according to claim 15, wherein an interface between the layer of the insulation material and a layer of the conductive material of the first element isolation portion is not in contact with the second element isolation portion in the cross section vertical to the substrate on which the semiconductor layer is laminated.

17. The photoelectric conversion apparatus according to claim 9, wherein the first photoelectric conversion element and the second photoelectric conversion element are photodiodes.

18. A method for manufacturing a photoelectric conversion apparatus, the method comprising:
disposing on a semiconductor layer a plurality of photoelectric conversion elements that each include a photoelectric conversion unit disposed on a side of a first surface of the semiconductor layer, and in which light of a light source enters from a side of a second surface opposite to the first surface of the semiconductor layer; and
forming a first element isolation portion that extends in the semiconductor layer from the first surface toward the second surface between a neighboring first photoelectric conversion element and second photoelectric conversion element of the plurality of photoelectric conversion elements, and includes a coated portion whose conductive material is coated with an insulation material containing silicon oxide, silicon nitride, silicon oxynitride, or a combination of the silicon oxide, the silicon nitride, and the silicon oxynitride,
wherein a film thickness of the insulation material in a cross section vertical to a substrate on which the semiconductor layer is laminated is 10 nm or more in a case where the insulation material is silicon nitride, 150 nm or more in a case where the insulation material is silicon oxide, and 50 nm or more in a case where the insulation material is silicon oxynitride.

19. The method for manufacturing the photoelectric conversion apparatus according to claim 18, further comprising forming a second element isolation portion made of an insulation material or a conductive material such that the second element isolation portion extends in the semiconductor layer from the second surface toward the first surface between the first photoelectric conversion element and the second photoelectric conversion element, and comes into contact with the first element isolation portion.

20. The method for manufacturing the photoelectric conversion apparatus according to claim 19, wherein the second element isolation portion is formed by etching the semiconductor layer in the forming of the second element isolation portion, and the etching is stopped before the insulation material of the coated portion is exposed and the conductive material of the coated portion is exposed.

21. Equipment that comprises the photoelectric conversion apparatus according to claim 1, further comprising at least one of:
an optical device that supports the photoelectric conversion apparatus;
a control device that controls the photoelectric conversion apparatus;
a processing device that processes a signal output from the photoelectric conversion apparatus;
a display device that displays information obtained by the photoelectric conversion apparatus;
a storage device that stores information obtained by the photoelectric conversion apparatus; and
a machine device that operates on a basis of information obtained by the photoelectric conversion apparatus.
